(19) United States
(12) Patent Application Publication
(10) Pub. No.: US 2024/0120222 A1
(43) Pub. Date: Apr. 11, 2024

(54) Load Port and Wafer Inspection Method Using the Same

(71) Applicants: Tsung-Che Yu, Taoyuan City (TW); Hsin-Jung Peng, Taoyuan City (TW); SHENG CHUAN TECHNOLOGY CO., LTD., Taoyuan City (TW)

(72) Inventor: Tsung-Che Yu, Taoyuan City (TW)

(21) Appl. No.: 18/176,570

(22) Filed: Mar. 1, 2023

(30) Foreign Application Priority Data
Oct. 6, 2022 (TW) 111138084

(51) Int. Cl. H01L 21/67; G01B 11/14; G01B 11/16

(52) U.S. Cl. CPC H01L 21/67265; G01B 11/14; G01B 11/16

(57) ABSTRACT

A load port includes a mounting base having: a movable plate; an opening portion mounted to a side of the mounting base through a board and having a driving assembly mounted on the board; and a movable door having a door panel, a lid-picking device and an inspection device mounted on a side surface of the door panel, and a connecting rod. The door panel is connected to the driving assembly and is movable relative to the board. The lid-picking device selectively closes a mounting opening of the board. When the load port carries a front opening unified pod (FOUP), it is able to inspect whether a wafer in the FOUP protrudes, tilts or overlaps with another wafer, and an amount of deformation of the wafer at the same time of opening the movable door, so as to reduce processing steps and improve production efficiency.

### BACKGROUND OF THE INVENTION

### 1. Field of the Invention

The present invention relates to a load port, especially to a load port for front opening unified pods (FOUPs).

### 2. Description of the Prior Art(s)

In today's semiconductor manufacturing processes, a wafer has to be processed in several workstations. While waiting between workstations, the wafers are placed in a front opening unified pod (FOUP) and the FOUP is placed on a load port, so as to store the wafers in a highly dust-free environment and to open or close a lid of the FOUP with the load port. By delivering gas, an interior of the FOUP can be kept dust-free when being opened or closed.

A conventional load port, as shown in U.S. Pat. No. 8,302,637 B2 and entitled “METHOD OF PROCESSING AN OBJECT INA CONTAINER AND LID OPENING/CLOSING SYSTEM USED IN THE METHOD”, discloses that purge gas supply nozzles are placed outside of two vertical sides of an opening portion within a front-opening interface mechanical standard (FIMS) system and a curtain nozzle is placed above a top side of the opening portion. When opening or closing a lid of a FOUP, the purge gas supply nozzles and the curtain nozzle eject gas to keep an interior of the FOUP clean.

However, the conventional load port as described is mainly used to carry the FOUP and open/close the lid of the FOUP. Since it takes a certain amount of time to open and close the lid, a lot of time is invisibly wasted in the manufacturing processes and thus manufacturing cost is increased.

To overcome the shortcomings, the present invention provides a load port and a wafer inspection method using the same to mitigate or obviate the aforementioned problems.

### SUMMARY OF THE INVENTION

The main objective of the present invention is to provide a load port that includes a mounting base, an opening portion, and a movable door. The mounting base has a top surface. A movable plate is mounted on the top surface, is movable relative to the mounting base, and is provided with a fastening element. The opening portion includes a board and a driving assembly. The board is mounted to a side of the mounting base and has a mounting opening and a guide opening. The mounting opening is disposed beside the movable plate. The driving assembly is mounted on the board and corresponds in position to the guide opening of the board. The movable door includes a door panel, a lid-picking device, an inspection device, and a connecting rod. The lid-picking device and the inspection device are mounted on a side surface of the door panel. The connecting rod is mounted on an end of the door panel. The movable door is connected to the driving assembly via the connecting rod, such that the door panel is movable relative to the board and the lid-picking device selectively closes the mounting opening.

The main objective of the present invention is to provide a wafer inspection method using the load port. The load port is configured to carry a front opening unified pod (FOUP) that has a front lid and is for storing multiple wafers. The wafer inspection method has steps of:
step 1: placing the FOUP on the movable plate of the mounting base;
step 2: connecting the fastening element of the movable plate with the FOUP;
step 3: moving the FOUP from a starting position to the mounting opening of the opening portion with the movable plate to make the front lid of the FOUP be connected with the lid-picking device of the movable door;
step 4: unlocking the front lid with the connecting elements of the lid-picking device and creating a vacuum, holding the front lid with the lid-picking device to move back to open the mounting opening;
step 5: driving the movable door with the driving assembly to move down the movable door to a predetermined distance and stop;
step 6: the two pivoting arms of the inspection device pivoting forward and moving forward until each of the inspection sensors on the two pivoting arms is aligned with a respective sensing position;
step 7: the movable door continuing to move downward when the inspection sensors are positioned, and the inspection sensors detecting whether each of the wafers protrudes, tilts or overlaps with the other wafer, and an amount of deformation of the wafer when the movable door moves downward;
step 8: the two pivoting arms of the inspection device pivoting backward to be folded, and the movable door moving upward and forward to close the mounting opening when the inspection is completed;
step 9: putting the front lid onto the FOUP and locking the front lid with the lid-picking device; and
step 10: locking the front lid with the lid-picking device locks and breaking the vacuum, and moving the FOUP back to the starting position with the fastening element disconnecting from the FOUP.

With the load port and the wafer inspection method using the load port, it is able to inspect the wafers at the same time of opening the movable door, so as to reduce processing steps and improve production efficiency.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a load port in accordance with the present invention;

FIG. 2 is an exploded perspective view of the load port in FIG. 1;

FIG. 3 is another exploded perspective view of the load port in FIG. 1;

FIG. 4 is an exploded perspective view of a movable door of the load port in FIG. 1;

FIG. 5 is an enlarged partially exploded perspective view of the load port in FIG. 1;

FIGS. 6 to 8 are operational side views of the load port in FIG. 1;

FIG. 9 is an enlarged perspective view of a second embodiment of a load port in accordance with the present invention; and

FIG. 10 is an enlarged side view of the load port in FIG. 9.

### DETAILED DESCRIPTION OF THE PREFERRED EMBODIMENTS

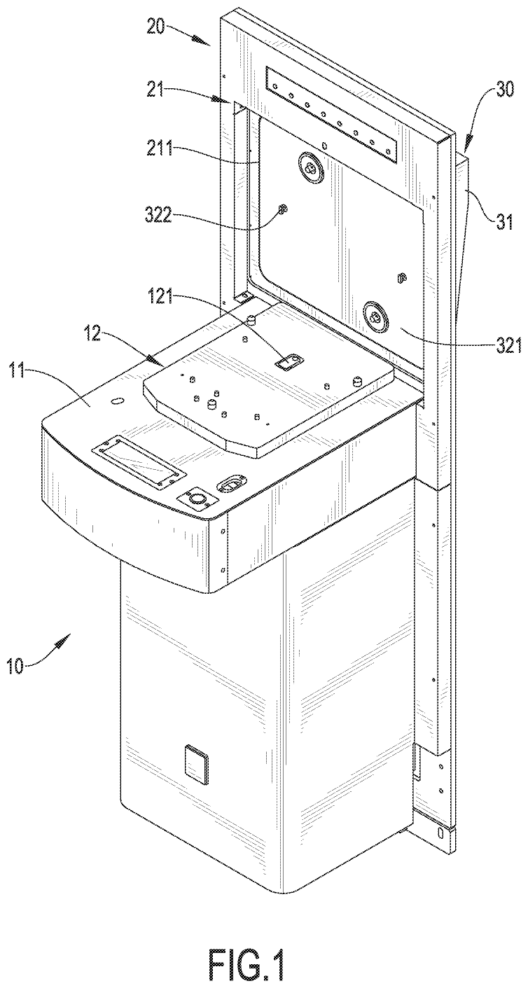

With reference to FIG. 1, a first embodiment of a load port in accordance with the present invention comprises a mounting base 10, an opening portion 20, and a movable door 30.

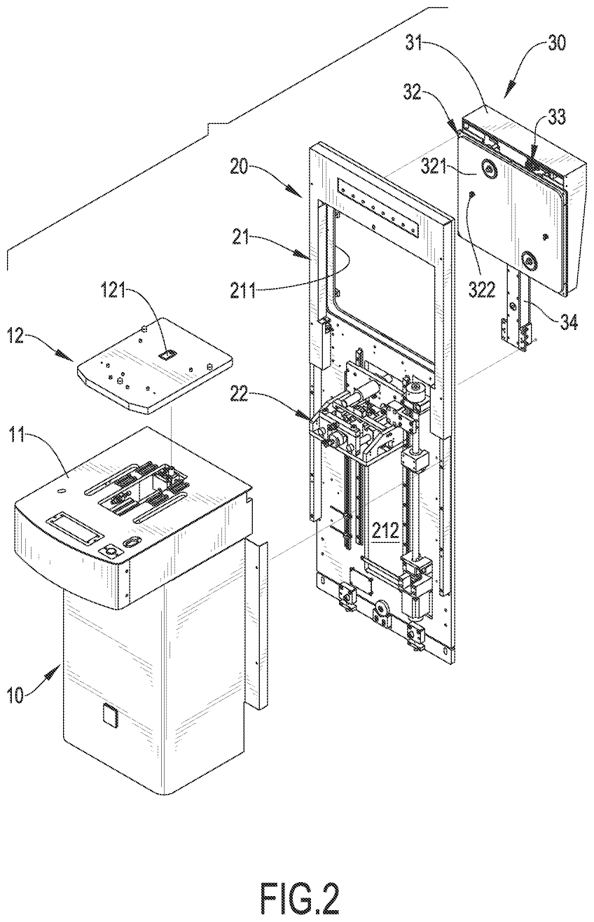

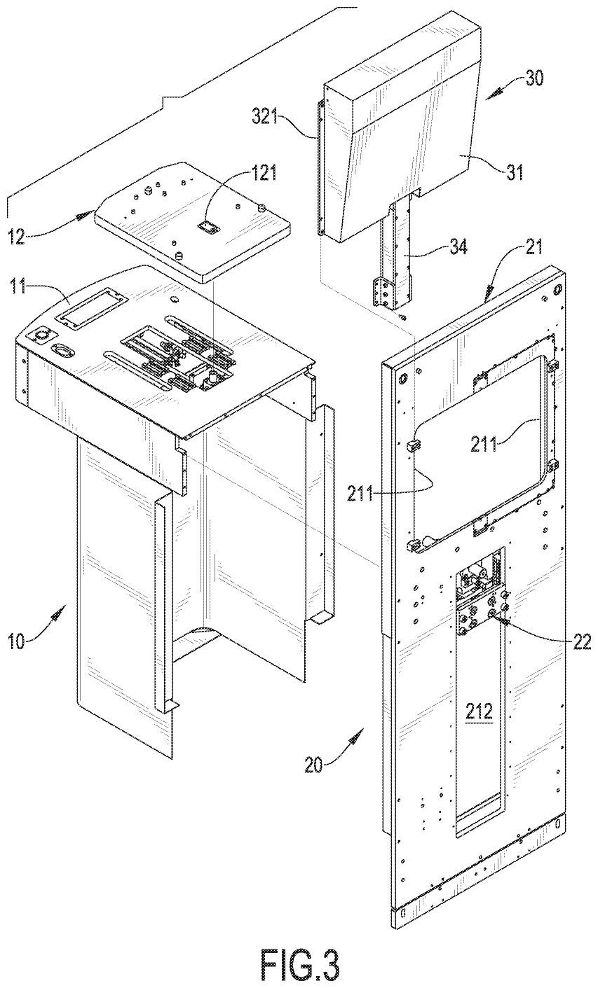

With further reference to FIGS. 2 and 3, the mounting base 10 has a top surface 11. A movable plate 12 is mounted on the top surface 11, is movable relative to the mounting base 10, and is provided with a fastening element 121. The fastening element 121 of the movable plate 12 and the way how the movable plate 12 moves are conventional and thus further descriptions thereof are omitted. Moreover, a further detailed structure of the movable plate 12 is not limited thereto, and the fastening element 121 may be omitted.

The opening portion 20 includes a board 21 and a driving assembly 22. The board 21 is mounted to a side of the mounting base 10 and has a mounting opening 211 and a guide opening 212. The mounting opening 211 is formed through the board 21 and is disposed beside the movable plate 12. The guide opening 212 is formed through the board 21 and is disposed below the mounting opening 211. The driving assembly 22 is mounted on the board 21, corresponds in position to the guide opening 212 of the board 21, and is linearly movable along the guide opening 212. In the preferred embodiment, the driving assembly 22 is movable up and down. The driving assembly 22 may include a stepper motor, a screw rod, at least one linear guide and so on. The driving assembly 22 is conventional and thus a further detailed structure thereof is omitted

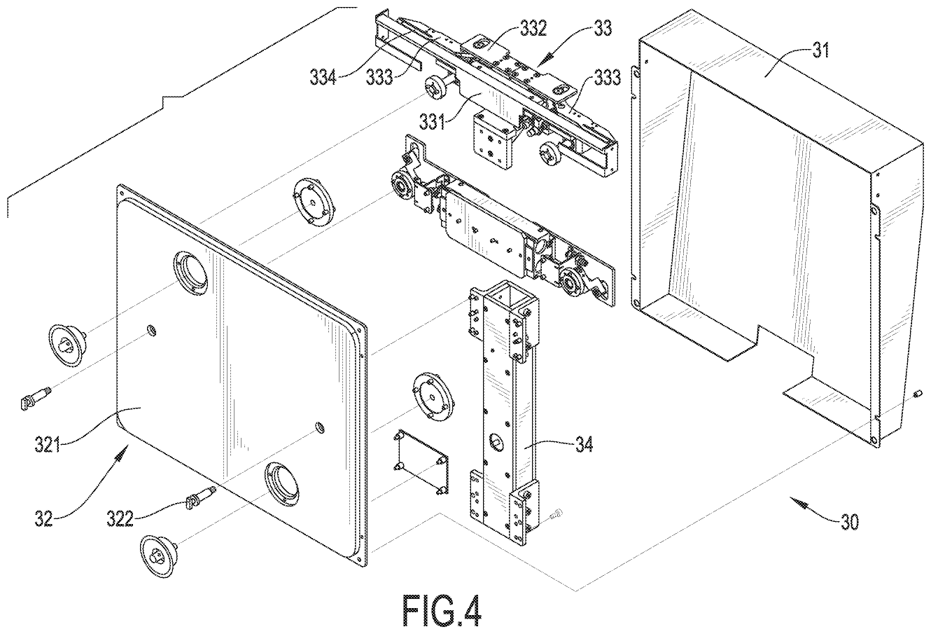

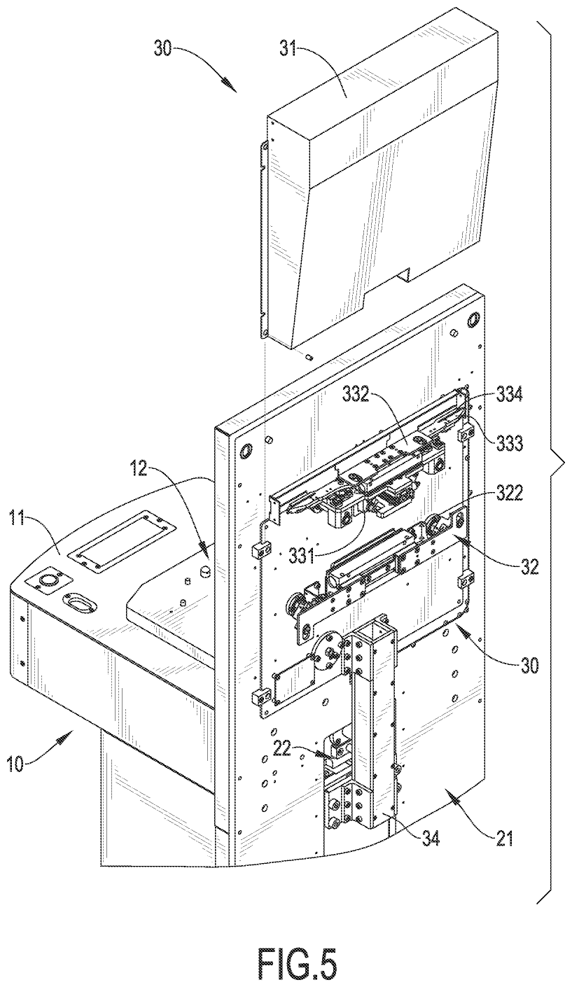

With further reference to FIGS. 2, 4 and 5, the movable door 30 includes a door panel 31, a lid-picking device 32, an inspection device 33, and a connecting rod 34. The door panel 31 has a recess formed in a side surface of the door panel 31. The lid-picking device 32 is mounted on the side surface of the door panel 31 and has a panel 321 and multiple connecting elements 322. The panel 321 is securely connected to the door panel 31 and covers the recess of the door panel 31. The connecting elements 322 are separately mounted on the panel 321. Each of the connecting elements 322 is a conventional component that is used to connect with a front lid of a front opening unified pod (FOUP) (not shown), and thus a further detailed structure thereof is omitted.

The inspection device 33 is mounted on the side surface of the door panel 31, is disposed between the door panel 31 and the lid-picking device 32, and includes a carrying bracket 331, a sliding rail assembly 332, two pivoting arms 333, and multiple inspection devices 334. The carrying bracket 331 is securely mounted on the panel 321 and is disposed in the recess of the door panel 31. The sliding rail assembly 332 is slidably mounted on the carrying bracket 331. Each of the pivoting arms 333 has a proximal end and a distal end. The proximal ends of the two pivoting arms 333 are pivotally connected to the sliding rail assembly 332 and are disposed apart from each other. The proximal end of each of the pivoting arms 333 is driven to rotate or to move linearly by a driving device. The way how the driving device drives the proximal end of the pivoting arm 333 to rotate or to move linearly is conventional and thus further descriptions thereof are omitted. The distal end of each of the pivoting arms 333 is provided with at least one of the inspection devices 334. In the preferred embodiment, each of the inspection devices 334 is a fiber optic sensor and may be used alone to send signals, or two or more of the fiber optic sensors may be used in an optional combination to mutually send and receive signals. A number and a formality of the inspection sensors 334 are not limited thereto and may be modified according to users' needs. The inspection device 33 is mounted on the panel 321 via the carrying bracket 331 and at an upper part of the panel 321, and is disposed in the recess of the door panel 31. The pivoting arms 333 are able to be pivoted to protrude outside of the panel 321.

The connecting rod 34 is mounted on an end of the door panel 31 and has two ends securely connected to the panel 321 and the driving assembly 22 respectively. The movable door 30 is connected to the driving assembly 22 via the connecting rod 34, such that the movable door 30 is movable relative to the board 21 and the panel 321 of the lid-picking device 32 is able to open or close the mounting opening 211.

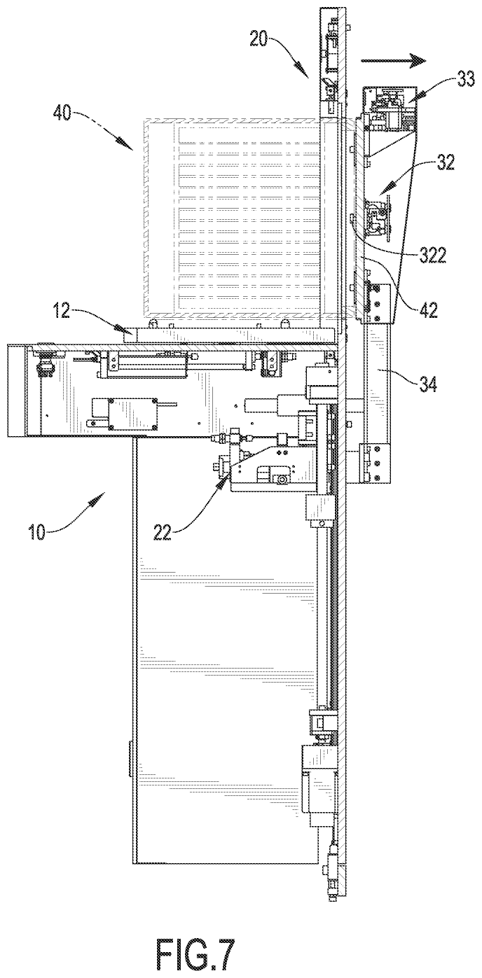

With further reference to FIGS. 3 and 6 to 8, take a FOUP 40 for storing multiple wafers (not shown) as an example. The FOUP 40 is a pod (front opening unified pod) with a front lid 42. A wafer inspection method in accordance with the present invention is performed by using the load port as described. The wafer inspection method comprises steps as follows.

In step 1, the FOUP 40 is placed on the movable plate 12 of the mounting base 10.

In step 2, the fastening element 121 of the movable plate 12 and the FOUP 40 are connected with each other.

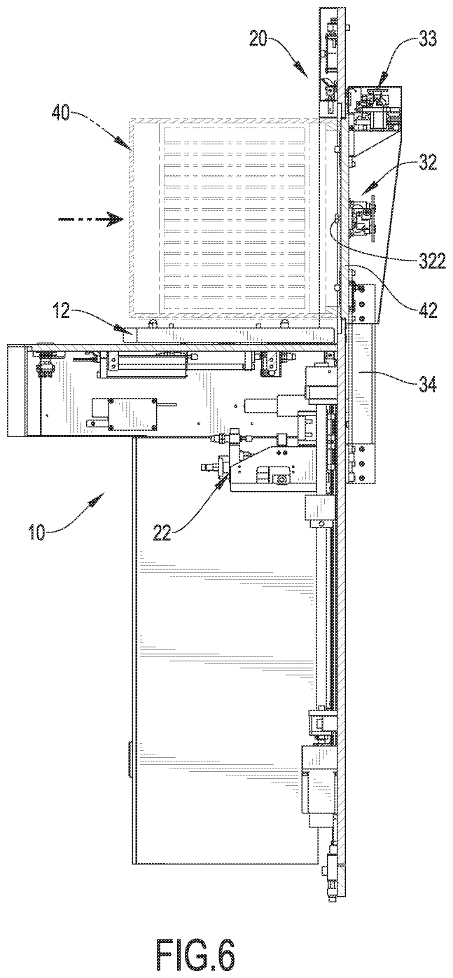

As shown in FIG. 6, in step 3, the movable plate 12 moves the FOUP 40 from a starting position to the mounting opening 211 of the opening portion 20 to make the front lid 42 of the FOUP 40 be connected with the lid-picking device 32 of the movable door 30.

In step 4, the lid-picking device 32 unlocks the front lid 42 with the connecting elements 322 and creates a vacuums, and then the lid-picking device 32 holds the front lid 42 and moves back to open the mounting opening 211.

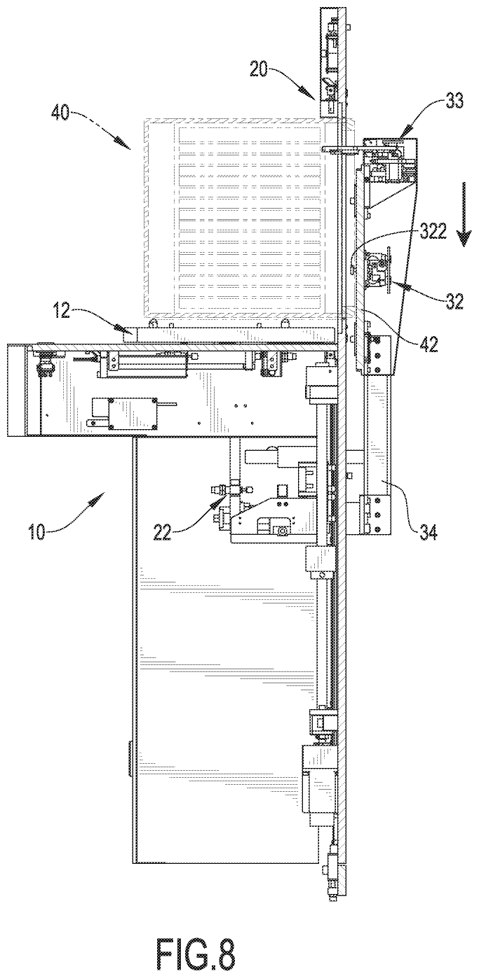

As shown in FIG. 8, in step 5, the movable door 30 is driven by the driving assembly 22 to move down a predetermined distance and stop.

In step 6, the two pivoting arms 333 of the inspection device 33 pivot forward and move forward until each of the inspection sensors 334 on the two pivoting arms 333 is aligned with a respective sensing position.

In step 7, when the inspection sensors 334 are positioned, the movable door 30 continues to move downward; when the movable door 30 moves downward, the inspection sensors 334 detect whether each of the wafers protrudes, tilts or overlaps with the other wafer, and an amount of deformation of the wafer.

In step 8, when the inspection is completed, the two pivoting arms 333 of the inspection device 33 pivot backward to be folded, and the movable door 30 moves upward and forward to close the mounting opening 211.

In step 9, the lid-picking device 32 puts the front lid 42 onto the FOUP 40 and locks the front lid 42.

In step 10, the lid-picking device 32 locks the front lid 42 and breaks the vacuum, and the FOUP 40 is moved back to the starting position with the fastening element 121 disconnecting from the FOUP 40.

With the load port and the aforementioned wafer inspection method, it is able to inspect the wafers at the same time of opening the movable door 30, so as to reduce processing steps and improve production efficiency. Moreover, by adjusting positions of the two pivoting arms 333 with the sliding rail assembly 332, it is able to inspect the wafers of different sizes.

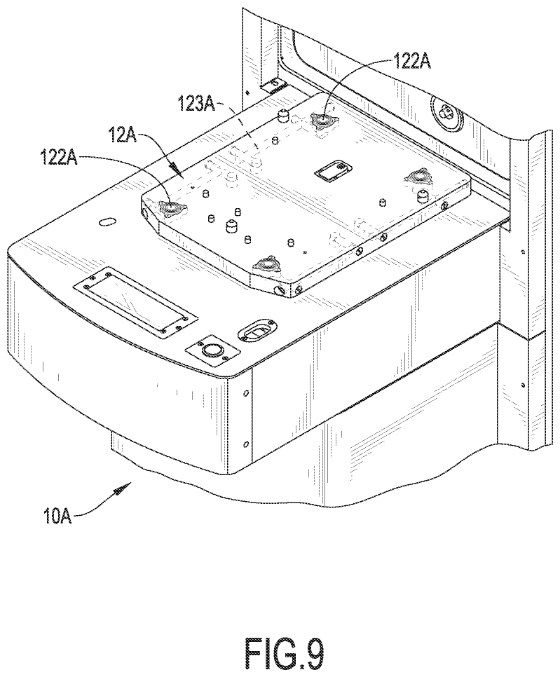

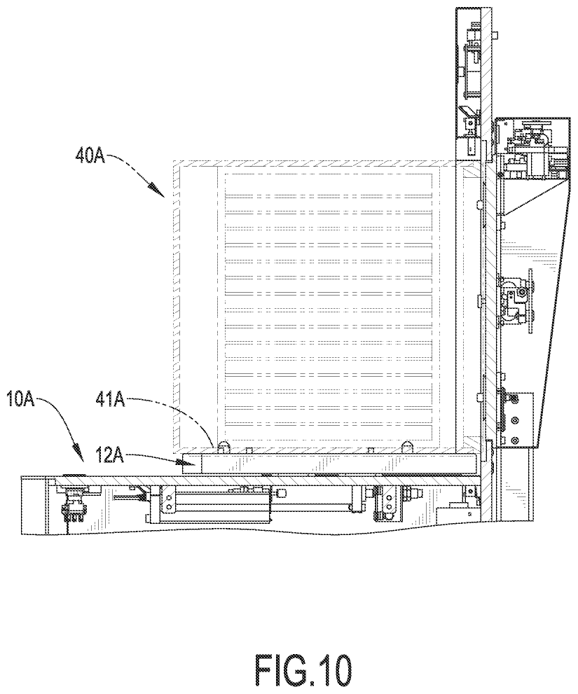

With further reference to FIGS. 9 and 10, a second embodiment of a load port in accordance with the present invention is shown. In the second embodiment of the load port, the opening portion 20 and the movable door 30 is the same as those in the first embodiment of the load port. The main difference is the mounting base 10A. In the second embodiment of the load port, the movable plate 12 further has multiple gas connectors 122A and multiple gas channels 123A. The gas connectors 122A are separately arranged. The gas channels 123A are formed in the movable plate 12A. Each of the gas channels 123A has two ends connected to a respective one of the gas connectors 122A and a gas supply device (not shown).

When in use, the FOUP 40A with multiple connecting holes 41A are mounted on the movable plate 12A, the connecting holes 41A are connected with the gas connectors 122A respectively. Thus, nitrogen from the gas supply device is able to fill the FOUP 40A through the gas connectors 122A, or the nitrogen may be drawn out of the FOUP 40A to prevent oxide formation of on a surface of each of the wafers.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A load port comprising:
a mounting base having a top surface, wherein a movable plate is mounted on the top surface, is movable relative to the mounting base, and is provided with a fastening element;
an opening portion including
a board mounted to a side of the mounting base and having a mounting opening and a guide opening, and the mounting opening disposed beside the movable plate; and
a driving assembly mounted on the board and corresponding in position to the guide opening of the board; and
a movable door including
a door panel;
a lid-picking device and an inspection device mounted on a side surface of the door panel; and
a connecting rod mounted on an end of the door panel, wherein the movable door is connected to the driving assembly via the connecting rod, such that the door panel is movable relative to the board and the lid-picking device selectively closes the mounting opening.

2. The load port as claimed in claim 1, wherein the inspection device includes:
a carrying bracket securely mounted on the panel;
a sliding rail assembly slidably mounted on the carrying bracket;
two rotating pivoting arms, each of the pivoting arms having a proximal end and a distal end, and the proximal ends of the two pivoting arms pivotally connected to the sliding rail assembly and disposed apart from each other; and
multiple inspection devices, wherein the distal end of each of the pivoting arms is provided with at least one of the inspection devices.

3. The load port as claimed in claim 1, wherein the lid-picking device has:
a panel securely connected to the door panel and selectively closes the mounting opening; and
multiple connecting elements separately mounted on the panel.

4. The load port as claimed in claim 2, wherein the lid-picking device has:
a panel securely connected to the door panel and selectively closes the mounting opening; and
multiple connecting elements separately mounted on the panel.

5. The load port as claimed in claim 3, wherein the movable plate further has:
multiple gas connectors separately arranged; and
multiple gas channels formed in the movable plate, and each of the gas channels connected to a respective one of the gas connectors.

6. The load port as claimed in claim 4, wherein the movable plate further has:
multiple gas connectors separately arranged; and
multiple gas channels formed in the movable plate, and each of the gas channels connected to a respective one of the gas connectors.

7. The load port as claimed in claim 2, wherein each of the inspection devices is a fiber optic sensor.

8. A wafer inspection method performed on the load port as claimed in claim 1, the load port configured to carry a front opening unified pod (FOUP) that has a front lid and is for storing multiple wafers, and the wafer inspection method comprising steps of:
step 1: placing the FOUP on the movable plate of the mounting base;
step 2: connecting the fastening element of the movable plate with the FOUP;
step 3: moving the FOUP from a starting position to the mounting opening of the opening portion with the movable plate to make the front lid of the FOUP be connected with the lid-picking device of the movable door;
step 4: unlocking the front lid with the connecting elements of the lid-picking device and creating a vacuum, holding the front lid with the lid-picking device to move back to open the mounting opening;
step 5: driving the movable door with the driving assembly to move down the movable door to a predetermined distance and stop;
step 6: the two pivoting arms of the inspection device pivoting forward and moving forward until each of the inspection sensors on the two pivoting arms is aligned with a respective sensing position;
step 7: the movable door continuing to move downward when the inspection sensors are positioned, and the inspection sensors detecting whether each of the wafers protrudes, tilts or overlaps with the other wafer, and an amount of deformation of the wafer when the movable door moves downward;
step 8: the two pivoting arms of the inspection device pivoting backward to be folded, and the movable door moving upward and forward to close the mounting opening when the inspection is completed;
step 9: putting the front lid onto the FOUP and locking the front lid with the lid-picking device; and
step 10: locking the front lid with the lid-picking device locks and breaking the vacuum, and moving the FOUP back to the starting position with the fastening element disconnecting from the FOUP.
